(19) United States
(12) Patent Application Publication
(10) Pub. No.: US 2006/0077729 A1
(43) Pub. Date: Apr. 13, 2006

(54) Low current consumption at low power DRAM operation

(75) Inventors: Yu-Chang Lin, Hsinchu (TW); Ming-Chun Wu, Hsinchu (TW)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Winbond Electronics Corp.

(21) Appl. No.: 10/959,164

(22) Filed: Oct. 7, 2004

(51) Int. Cl. G11C 7/00

(52) U.S. Cl. 365/189.11

(57) ABSTRACT

A memory device connectable to an external power supply voltage, includes an array of memory cells defined by a plurality of bit lines and a plurality of word lines, each memory cell corresponding to a respective bit line and a respective word line; an equalization circuit for equalizing the plurality of bit lines during a pre-charge process; a multiplexing circuit for selecting one or more of the plurality of bit lines; a plurality of word line control circuits each for controlling a selection of a respective one of the plurality of word lines; a first voltage generator coupled to provide a first power supply voltage to the plurality of word line control circuits; and a second voltage generator coupled to provide a second power supply voltage to the equalization circuit and the multiplexing circuit, wherein the second power supply voltage is lower than the first power supply voltage.

### TECHNICAL FIELD

This invention relates in general to a memory device and, more particularly, to a DRAM device having a higher power consumption efficiency than conventional DRAM devices.

### BACKGROUND INFORMATION

In recent years, dynamic random access memories (DRAMs) have been widely used in mobile phones that require low power supplies for DRAMs. For example, an external power supply voltage V_{EXT} of a DRAM suitable for use in a mobile phone may be 1.8V as compared to a traditional DRAM device that is operable at 2.5V. Also, a DRAM must be refreshed regularly to avoid the loss of information stored in the memory cells thereof. How to realize low power supply and low self-refresh current consumption becomes a focus of circuit designers' research. A conventional DRAM circuit and the operating voltages thereof are discussed below with reference to FIGS. 1 and 2.

FIG. 1 shows part of a conventional DRAM 100 that is connectable to external power supply V_{EXT}. DRAM 100 may include an array of memory cells, a plurality of bit lines, and a plurality of word lines. Each memory cell corresponds to a bit line and a word line and includes an MOS transistor coupled to the respective bit line and word line and a capacitor coupled to the MOS transistor. Charges stored in the capacitor represent a status of the respective memory cell. Peripheral circuits of DRAM 100 operate to read, erase, or write each memory cell through the MOS transistor thereof. In FIG. 1, two memory cells 102 and 104 are shown, wherein cell 102 corresponds to a word line WL1 and a bit line BL1 and cell 104 corresponds to a word line WL2 and a bit line BL2. Cell 102 includes an NMOS transistor 106 and a capacitor 108 and cell 104 includes an NMOS transistor 110 and a capacitor 112. NMOS transistors 106 and 110 each have a gate (not numbered), a source (not numbered), and a drain (not numbered). Capacitors 108 and 112 each have a first terminal and a second terminal. The first terminals of capacitors 108 and 112 are coupled to a power supply voltage V_{PL}, wherein V_{PL} may be ground. The second terminal of capacitor 108 is coupled to the source of NMOS transistor 106 and the second terminal of capacitor 112 is coupled to the source of NMOS transistor 110. The gate of NMOS transistor 106 is coupled to word line WL1 and the drain of NMOS transistor 106 is coupled to bit line BL1. The gate of NMOS transistor 110 is coupled to word line WL2 and the drain of NMOS transistor 110 is coupled to bit line BL2.

Also shown in FIG. 1 are an equalization circuit 114 for equalizing bit lines BL1 and BL2 during a precharge process, an equalization control circuit 116 for controlling the precharge process, a multiplexing circuit 118 for selecting at least one bit line, a multiplexing control circuit 120 for controlling the selection of a bit line, and word line control circuits 122 and 124 for controlling or selecting word lines WL1 and WL2, respectively. Equalization circuit 114 includes three MOS transistors 126, 128, and 130 coupled to one another as shown in FIG. 1. Multiplexing circuit 118 includes MOS transistors 132 and 134 coupled to each other as shown in FIG. 1.

As shown in FIG. 1, equalization circuit 114 is coupled to a bit line equalization voltage V_{BLEQ}, and word line control circuits 122 and 124 are coupled to a power supply voltage V_{PP}. DRAM 100 also includes other peripheral circuits, shown in FIG. 1 as an internal circuit 136, that are powered by an internal power supply voltage V_{INT}. V_{BLEQ} is generally lower than V_{EXT}. V_{INT} is generally equal to or lower than V_{EXT}. V_{PP} is generally higher than V_{EXT}. The power supply voltage to equalization circuit 114 is denoted as V_{EQL}, and the power supply voltage to multiplexing circuit 118 is denoted as V_{MUX}, as shown in FIG. 1. Generally, V_{INT} may be provided to equalization control circuit 116 for supplying V_{EQL} to equalization circuit 114. For a sense amplifier (not shown) in DRAM 100 to sense the full level of bit line logic, V_{MUX} must be greater than _{VBL}(max)+Vₜₕₙ, wherein V_{BL}(max) is the maximum voltage on the bit lines such as BL1 or BL2. V_{MUX} is generally greater than V_{EXT} and are supplied by V_{PP}, as shown in FIG. 1. Thus, as shown in FIG. 2, the level of V_{EQL} is between V_{INT} and 0V, V_{MUX} is between V_{PP} and V_{INT}, and the level of V_{WL} is between V_{PP} and 0V, wherein V_{WL} denotes the voltage level on the word lines such as WL1 or WL2.

Referring again to FIG. 1, power supply voltages V_{BLEQ}, V_{PP}, and V_{INT} are generated from V_{EXT} by a V_{BLEQ} generator 138, a V_{PP} generator 140, and a V_{INT} generator 142, respectively. V_{BLEQ} generator 138 and V_{INT} generator 142 may each be a voltage divider or a reference voltage generator, which is well known to one skilled in the art. However, since V_{PP} is generally higher than V_{EXT}, V_{PP} generator 140 must be implemented as a booster circuit or pump circuit, which is well known to one skilled in the art and is not described in detail herein.

The booster circuit or pump circuit for generating V_{PP} in conventional DRAM applications generally has a low efficiency, which greatly increases the power consumption of DRAM 100. For example, in some applications, V_{INT}=V_{EXT}=2.5V, V_{PP}=3.2V, V_{BLEQ}=0.8V, and a pumping efficiency for generating V_{PP} is 45%, wherein the pumping efficiency is defined as the ratio of the current consumed by generated V_{PP} to the current consumed by external power supply V_{EXT}. In other words, for every 1 mA consumed by V_{PP}, V_{EXT} would consume a current of 1 mA/45%=2.22 mA.

For some applications where the nominal power supply voltage of a DRAM device is 1.8V, the DRAM device generally needs to be operative at V_{EXT}=1.6V or even less. Thus, assuming a V_{PP} of 3.2V, the pumping efficiency for generating V_{PP} is 28%. In other words, for every 1 mA consumed by V_{PP}, the current consumed by V_{EXT} would be 1 mA/28%=3.57 mA.

### SUMMARY OF THE INVENTION

Embodiments of the present invention are in general directed to novel DRAM devices that obviate one or more of the problems due to limitations and disadvantages of the related art.

Consistent with embodiments of the present invention, there is provided a memory device connectable to an external power supply voltage. The memory device includes an array of memory cells defined by a plurality of bit lines and a plurality of word lines, each memory cell corresponding to a respective bit line and a respective word line; an equalization circuit for equalizing the plurality of bit lines during a pre-charge process; a multiplexing circuit for selecting one or more of the plurality of bit lines; a plurality of word line control circuits each for controlling a selection of a respective one of the plurality of word lines; a first voltage generator coupled to provide a first power supply voltage to the plurality of word line control circuits; and a second voltage generator coupled to provide a second power supply voltage to the equalization circuit and the multiplexing circuit, wherein the second power supply voltage is lower than the first power supply voltage.

Consistent with embodiments of the present invention, there is also provided a method of operating a memory device, wherein the memory device is connectable to an external power supply voltage and includes a plurality of memory cells each defined by one of a plurality of word lines and one of a plurality of bit lines, a plurality of word line control circuits each for controlling a selection of a respective one of the plurality of word lines, an equalization circuit for equalizing the plurality of bit lines during a pre-charge process, and a multiplexing circuit for selecting one or more of the plurality of bit lines. The method includes providing a first power supply voltage to the plurality of word line control circuits; and providing a second power supply voltage to the equalization circuit and the multiplexing circuit, wherein the second power supply voltage is lower than the first power supply voltage.

Additional features and advantages of the invention will be set forth in part in the description which follows, and in part will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are incorporated in and constitute a part of this specification, illustrate embodiments of the invention and, together with the description, serve to explain the features, advantages, and principles of the invention.

In the drawings:

FIG. 1 shows a circuit diagram of a part of a conventional memory device;

FIG. 2 graphically illustrates the levels of several power supply voltages in the conventional memory device of FIG. 1;

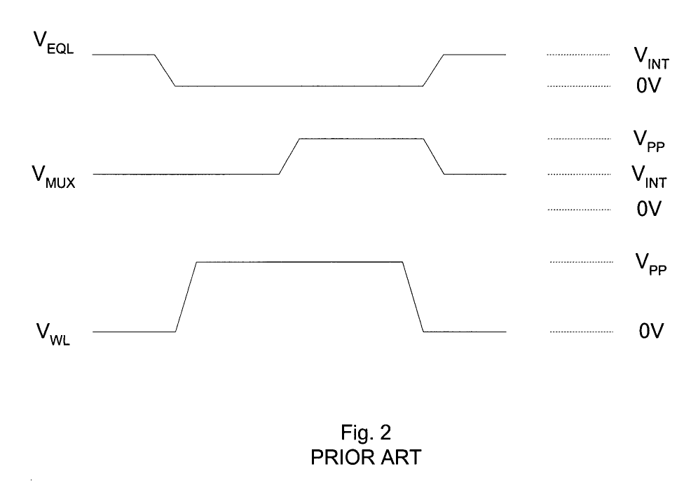

FIG. 3 shows a circuit diagram of a part of a memory device consistent with embodiments of the present invention; and

FIG. 4 graphically illustrates the levels of several power supply voltages in the memory device of FIG. 3.

### DESCRIPTION OF THE EMBODIMENTS

Reference will now be made in detail to embodiments of the present invention, examples of which are illustrated in the accompanying drawings. Wherever possible, the same reference numbers will be used throughout the drawings to refer to the same or like parts.

Embodiments of the present invention are in general directed to DRAM devices with lower power consumptions than conventional DRAM devices.

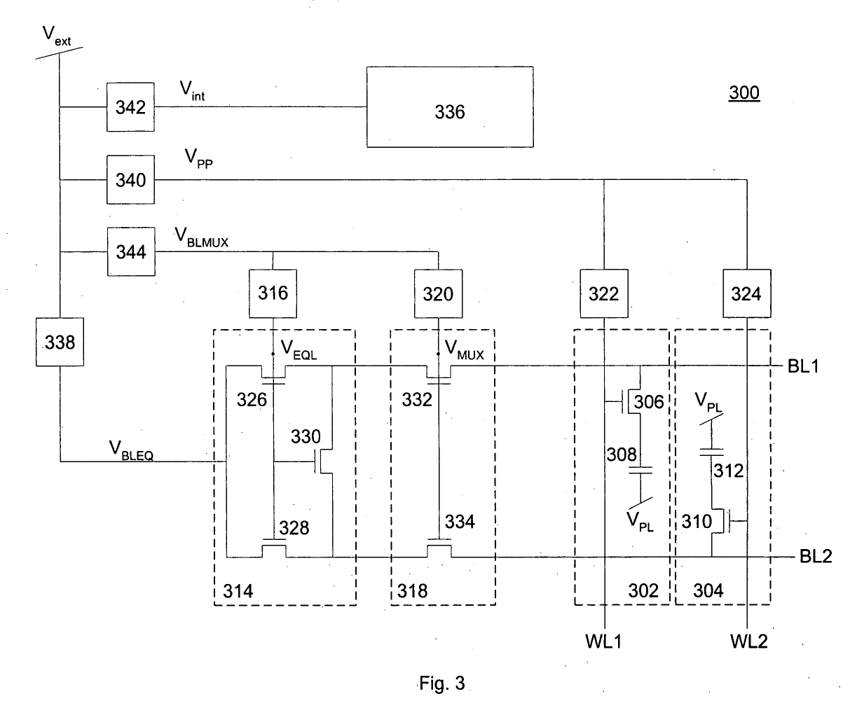

FIG. 3 shows a circuit diagram of a part of a DRAM device 300 consistent with the present invention. DRAM 300 is connectable to an external power supply voltage V_{EXT}, and may include an array of memory cells defined by a plurality of bit lines and a plurality of word lines, each memory cell corresponding to a bit line and a word line. Only two memory cells 302 and 304 of DRAM 300 are shown in FIG. 3, wherein cell 302 corresponds to a word line WL1 and a bit line BL1 and cell 304 corresponds to a word line WL2 and a bit line BL2. Cell 302 includes an NMOS transistor 306 and a capacitor 308 and cell 304 includes an NMOS transistor 310 and a capacitor 312. NMOS transistors 306 and 310 each have a gate (not numbered), a source (not numbered), and a drain (not numbered). Capacitors 308 and 312 each have a first terminal and a second terminal. The first terminals of capacitors 308 and 312 are coupled to a power supply voltage V_{PL}. The second terminal of capacitor 308 is coupled to the source of NMOS transistor 306 and the second terminal of capacitor 312 is coupled to the source of NMOS transistor 310. The gate of NMOS transistor 306 is coupled to word line WL1 and the drain of NMOS transistor 306 is coupled to bit line BL1. The gate of NMOS transistor 310 is coupled to word line WL2 and the drain of NMOS transistor 310 is coupled to bit line BL2. DRAM 300 also includes an equalization circuit 314 for equalizing bit lines BL1 and BL2 during a precharge process, an equalization control circuit 316 for controlling the precharge process, a multiplexing circuit 318 for selecting at least one bit line, a multiplexing control circuit 320 for controlling the selection of a bit line, and word line control circuits 322 and 324 for controlling or selecting word lines WL1 and WL2, respectively. Equalization circuit 314 includes three MOS transistors 326, 328, and 330 coupled to one another as shown in FIG. 3. Multiplexing circuit 318 includes MOS transistors 332 and 334 coupled to each other as shown in FIG. 3.

Equalization circuit 314 is coupled to a bit line equalization voltage V_{BLEQ}, and word line control circuits 322 and 324 are coupled to a power supply voltage V_{PP}. DRAM 300 also includes other peripheral circuits, collectively as an internal circuit 336, that are powered by an internal power supply voltage V_{INT}. V_{BLEQ} is generally lower than V_{EXT}. V_{INT} is generally equal to or lower than V_{EXT}. V_{PP} is generally higher than V_{EXT} The power supply voltage to equalization circuit 314 is denoted as V_{EQL}, and the power supply voltage to multiplexing circuit 318 is denoted as V_{MUX}, as shown in FIG. 3. To maintain equalization between bit line pairs, V_{EQL} must be greater than V_{BLEQ}+Vₜₕₙ, wherein Vₜₕₙ is a threshold voltage of NMOS transistors 326 and 328. Also, for a sense amplifier (not shown) in DRAM 300 to sense the full level of bit line logic, V_{MUX} must be greater than V_{BL}(max)+Vₜₕₙ, wherein V_{BL}(max) is the maximum voltage on the bit lines such as BL1 or BL2. Therefore, both V_{EQL} and V_{MUX} are generally greater than V_{EXT}.

Still referring to FIG. 3, V_{BLEQ}, V_{PP}, and V_{INT} are generated from V_{EXT} by a V_{BLEQ} generator 338, a V_{PP} generator 340, and a V_{INT} generator 342, respectively. V_{BLEQ} generator 338 and V_{INT} generator 342 may each be a voltage divider or a reference voltage generator, while V_{PP} generator 340 is implemented as a booster circuit or pump circuit. Voltage dividers, reference voltage generators, booster circuits, and pump circuits are well known to one skilled in the art and are not described in detail herein.

Consistent with the embodiment of the present invention, a power supply voltage V_{BLMUX} generated by a V_{BLMUX} generator 344 is provided to equalization control circuit 316 and multiplexing circuit 320. The power supply voltages to equalization circuit 314 and multiplexing circuit 318, i.e., V_{EQL} and V_{MUX}, may generally reach a level of the power supply voltage to the equalization control circuit 316 and multiplexing circuit 320, respectively. V_{BLMUX} may be higher than V_{INT} but lower than V_{PP}. V_{BLMUX} generator 344 may be implemented as a booster circuit or a pump circuit.

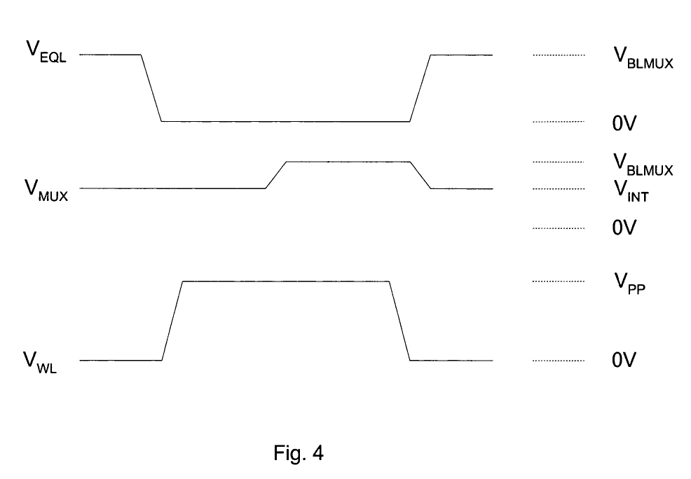

FIG. 4 shows the power levels of V_{EQL}, V_{MUX}, and V_{WL}, consistent with an embodiment of the present invention. As shown in FIG. 4, the level of V_{EQL} is between V_{BLMUX} and 0V, V_{MUX} is between V_{BLMUX} and V_{INT}, and the level of V_{WL} is between V_{PP} and 0V, wherein V_{WL} denotes the voltage level on the word lines such as WL1 or WL2.

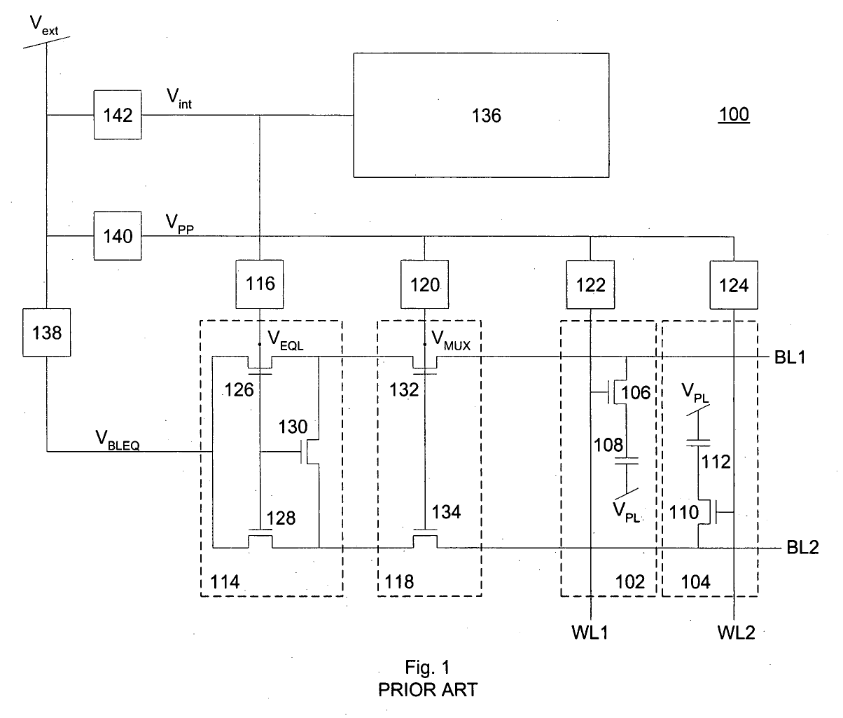

By providing a power supply voltage that is lower than V_{PP} but sufficient for equalization circuit 314 and multiplexing circuit 318, a power consumption of DRAM 300 is lowered as compared with conventional DRAM devices, such as DRAM 100 shown in FIG. 1. For example, in an application where V_{EXT} is approximately 1.8V and V_{PP} is approximately 3.2V, V_{BLMUX} may be chosen to be approximately 2.5V. Thus, a pumping efficiency of V_{BLMUX} generator 344 is approximately 41% (assuming an actual V_{EXT} of 1.6V), much higher than the efficiency of generating V_{PP}, which is 28% as discussed in the above. In other words, for every 1 mA consumed by V_{BLMUX}, the current consumed by V_{EXT} would be 1 mA/41%=2.44 mA. One skilled in the art should now understand that V_{EQL}, V_{MUX}, V_{WL}, V_{BLMUX}, V_{PP}, V_{INT}, are V_{EXT} may have different levels and are not limited to the these exemplary values.

In a DRAM device, the equalization circuit and multiplexing circuit (such as 314 and 318) include transistors that are larger in size than the transistors in the memory cells, and therefore consume the most current in the DRAM device. By providing V_{BLMUX} rather than V_{PP} to equalization circuit 314 and multiplexing circuit 318, a power consumption of DRAM 300 is significantly reduced.

It will be apparent to those skilled in the art that various modifications and variations can be made in the disclosed structures and methods without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A memory device connectable to an external power supply voltage, comprising
an array of memory cells defined by a plurality of bit lines and a plurality of word lines, each memory cell corresponding to a respective bit line and a respective word line;
an equalization circuit for equalizing the plurality of bit lines during a pre-charge process;
a multiplexing circuit for selecting one or more of the plurality of bit lines;
a plurality of word line control circuits each for controlling a selection of a respective one of the plurality of word lines;
a first voltage generator coupled to provide a first power supply voltage to the plurality of word line control circuits; and
a second voltage generator coupled to provide a second power supply voltage to the equalization circuit and the multiplexing circuit, wherein the second power supply voltage is lower than the first power supply voltage.

2. The memory device of claim 1, wherein the second power supply voltage is higher than the external power supply voltage.

3. The memory device of claim 1, wherein the external power supply voltage is 1.8V, the first power supply voltage is 3.2V, and the second power supply voltage is 2.5V.

4. The memory device of claim 1, wherein the first voltage generator comprises a booster circuit or a pump circuit.

5. The memory device of claim 1, wherein the second voltage generator comprises a booster circuit or a pump circuit.

6. The memory device of claim 1, wherein the first and second voltage generators are connectable to the external power supply voltage.

7. The memory device of claim 1, further comprising a third voltage generator coupled to provide a third power supply voltage to the equalization circuit, wherein the third power supply voltage is lower than the external power supply voltage and the third voltage generator is connectable to the external power supply voltage.

8. The memory device of claim 1, further comprising a peripheral circuit connectable to an internal power supply voltage.

9. The memory device of claim 8, further comprising a fourth voltage generator coupled to provide the internal power supply voltage to the peripheral circuit.

10. The memory device of claim 8, wherein the internal power supply voltage is not greater than the external power supply voltage.

11. A method of operating a memory device, wherein the memory device is connectable to an external power supply voltage and includes a plurality of memory cells each defined by one of a plurality of word lines and one of a plurality of bit lines, a plurality of word line control circuits each for controlling a selection of a respective one of the plurality of word lines, an equalization circuit for equalizing the plurality of bit lines during a pre-charge process, and a multiplexing circuit for selecting one or more of the plurality of bit lines, the method comprising:
providing a first power supply voltage to the plurality of word line control circuits; and
providing a second power supply voltage to the equalization circuit and the multiplexing circuit, wherein the second power supply voltage is lower than the first power supply voltage.

12. The method of claim 11, wherein providing the second power supply voltage includes providing the second power supply voltage to be higher than the external power supply voltage.

13. The method of claim 11, wherein the external power supply voltage is 1.8V, and wherein providing the first power supply voltage includes providing the first power supply voltage as 3.2V, and providing the second power supply voltage includes providing the second power supply voltage as 2.5V.

14. The method of claim 11, wherein providing the first power supply voltage comprises providing the first power supply voltage using a booster circuit or a pump circuit.

15. The method of claim 11, wherein providing the second power supply voltage comprises providing the second power supply voltage using a booster circuit or a pump circuit.

16. The method of claim 11, further comprising providing a third power supply voltage to the equalization circuit, wherein the third power supply voltage is lower than the external power supply voltage.

17. The method of claim 11, wherein the memory device further comprises a peripheral circuit connectable to an internal power supply voltage, and the method further comprises providing the internal power supply voltage to the peripheral circuit.

18. The method of claim 17, wherein providing the internal power supply voltage includes providing the internal power supply voltage to be not greater than the external power supply voltage.
